(19) United States
(12) Patent Application Publication
(10) Pub. No.: US 2024/0401189 A1
(43) Pub. Date: Dec. 5, 2024

(54) FORMATION OF MEMORY DEVICE CHANNEL HOLES USING DOPED FILM LAYER

(71) Applicant: Applied Materials, Inc., Santa Clara, CA (US)

(72) Inventors: Hsiang Yu LEE, Cupertino, CA (US); Changwoo SUN, Santa Clara, CA (US); Milan PESIC, Paoli, PA (US); Pradeep SUBRAHMANYAN, Cupertino, CA (US)

(73) Assignee: Applied Materials, Inc., Santa Clara, CA (US)

(21) Appl. No.: 18/671,184

(22) Filed: May 22, 2024

Related U.S. Application Data
(60) Provisional application No. 63/470,647, filed on Jun. 2, 2023.

(51) Int. Cl. C23C 16/04; C23C 16/24; C23C 16/34; C23C 16/40

(52) U.S. Cl. CPC C23C 16/045; C23C 16/24; C23C 16/34; C23C 16/40

(57) ABSTRACT

Disclosed are approaches for to fabricating memory device channel holes using a doped film layer. One approach may include providing a substrate and forming a vertical stack over the substrate, wherein the vertical stack includes a plurality of alternating material layers. The method may further include forming a channel hole through the vertical stack, forming an oxide-nitride-oxide layer along a sidewall of the channel hole, forming a silicon layer over the oxide-nitride-oxide layer, forming an etch stop layer over the silicon layer, forming a fluorine-doped silicon layer over the etch step layer, and annealing the vertical stack.

### RELATED APPLICATION

This application claims priority to U.S. provisional patent application Ser. No. 63/470,647, filed on Jun. 2, 2023, entitled “Fluorine Doping of Manos Structure to Control State Spread,” which is incorporated herein by reference in its entirety.

### FIELD

The present disclosure relates to processing of three-dimensional NAND devices and, more particularly, to formation of memory device channel holes using a doped film layer.

### BACKGROUND

A memory design known as NAND memory is a non-volatile flash memory storage architecture that does not require power to maintain its stored data. NAND flash memory is used in many products, such as solid-state devices and portable electronics. In order to improve the density and reduce the size of NAND memories, traditional two-dimensional NAND architectures have transitioned to three-dimensional (3D) NAND stacks. Unlike two-dimensional (2D) planar NAND technologies where the individual memory cells are stacked together on separate horizontal substrates, 3D NAND is stacked vertically using multiple layers of alternating conducting and dielectric materials with intersecting vertical channels.

Logical scaling to store more bits in a cell is one way to increase memory capacity and reduce bit cost in 3D NAND memory. However, the intrinsic channel effect increases threshold voltage distribution and reduces ON current by increasing the channel resistance. It is with respect to these and other considerations that the present disclosure is provided.

### SUMMARY OF THE DISCLOSURE

In view of the foregoing, in some approaches, a method may include forming a channel hole through a vertical stack, wherein the vertical stack includes a plurality of alternating material layers, and forming a tunneling layer along a sidewall of the channel hole. The method may further include forming a channel layer over the oxide-nitride-oxide layer, forming an etch stop layer over the channel layer and, forming a doped film layer over the etch step layer, and annealing the vertical stack.

In some approaches, a method of fabricating a three-dimensional (3D) NAND memory structure may include providing a substrate, and forming a vertical stack over the substrate, the vertical stack including a plurality of alternating material layers. The method may further include forming a channel hole through the vertical stack, forming an oxide-nitride-oxide layer along a sidewall and along a bottom of the channel hole, forming a silicon layer over the oxide-nitride-oxide layer, forming an etch stop layer over the silicon layer, forming a fluorine-doped silicon layer over the etch step layer, and annealing the vertical stack.

In some approaches, a method of forming a memory device may include forming a vertical stack over a substrate, the vertical stack comprising a plurality of alternating material layers, and forming a channel hole through the vertical stack. The method may further include forming an oxide-nitride-oxide layer along a sidewall and along a bottom of the channel hole, forming a silicon layer over the oxide-nitride-oxide layer, forming an etch stop layer over the silicon layer, forming a fluorine-doped silicon film over the etch step layer, and annealing the vertical stack including the fluorine-doped silicon film.

### BRIEF DESCRIPTION OF THE DRAWINGS

FIG. 1 illustrates a top plan view of a processing system, according to some embodiments.

FIGS. 2A-2D illustrate incremental stages for generating a memory structure with channels, according to some embodiments.

FIGS. 3A-3E illustrate incremental stages for generating one or more channels of the memory structure, according to some embodiments.

FIG. 4 illustrates a flowchart of a method for fabricating a 3D NAND memory structure, according to some embodiments.

The drawings are not necessarily to scale. The drawings are merely representations, not intended to portray specific parameters of the disclosure. The drawings are intended to depict exemplary embodiments of the disclosure, and therefore are not to be considered as limiting in scope.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

Embodiments herein are directed to 3-D NAND devices including a fluorine-doped metal-alumina-silicon nitride-silicon dioxide-silicon (MANOS) structure to control state spread. More specifically, embodiments herein provide an integration solution to deposit fluorine-doped silicon (Si) within one or more stack trenches, which will act as a solid source to enable fluorine diffusion and to passivate Si channel/tunnel SiO interface in the 3D NAND structure. Fluorine passivation increases the ON current, which enables further wordline stacking, and also improves subthreshold swing and threshold voltage, which makes the material-inherent distribution narrower to reduce the power required for squeezing sixteen (16) states and beyond. The fluorine-doped silicon is thick enough to fill the top channel hole yet still create a void inside. An annealing step to the structure causes chlorine diffusion inside the channel to passivate the channel and tunnel the oxide interface. The fluorine-doped silicon film is then removed by an etch, while the void broadens the removal process window.

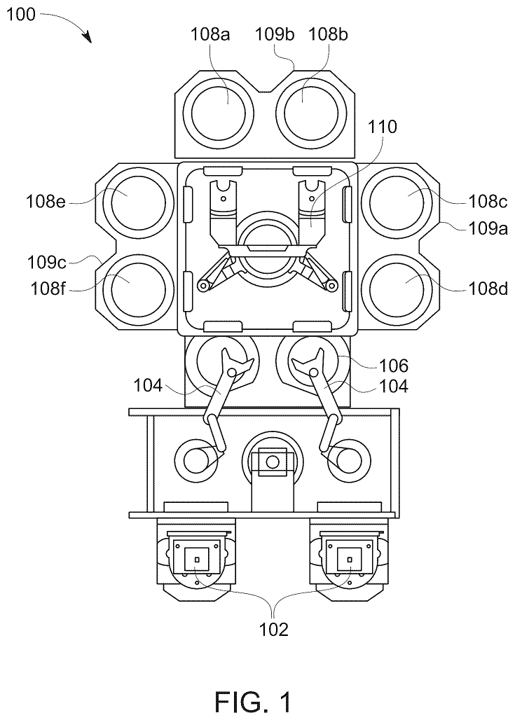

FIG. 1 illustrates a top plan view of one embodiment of a processing system 100 of deposition, etching, baking, and curing chambers according to some embodiments. As shown, a pair of front opening unified pods 102 supply substrates of a variety of sizes that are received by robotic arms 104 and placed into a low-pressure holding area 106 before being placed into one of the substrate processing chambers 108a-f, positioned in tandem sections 109a-c. A second robotic arm 110 may be used to transport the substrate wafers from the holding area 106 to the substrate processing chambers 108a-f and back. Each substrate processing chamber, 108a-f, can be outfitted to perform a number of substrate processing operations including the etch processes described herein in addition to cyclical layer deposition, atomic layer deposition, chemical vapor deposition, physical vapor deposition, etch, pre-clean, anneal, plasma processing, degas, orientation, and other substrate processes.

The substrate processing chambers 108a-f may include one or more system components for depositing, annealing, curing and/or etching a material film on the substrate or wafer, such as the fluorine doped layer. In one configuration, two pairs of the processing chambers, for example 108c-d and 108e-f, may be used to deposit material (e.g., one or more films) on the substrate, and the third pair of processing chambers, for example 108a-b, may be used to cure, anneal, or treat the deposited films. In another configuration, all three pairs of chambers, for example 108a-f, may be configured to both deposit and cure a film on the substrate. Any one or more of the processes described may be carried out in additional chambers separated from the fabrication system shown in different embodiments. It will be appreciated that additional configurations of deposition, etching, annealing, and curing chambers for material films are contemplated by the processing system 100.

Additionally, any number of other processing systems may be utilized with the present technology, which may incorporate chambers for performing any of the specific operations. In some embodiments, chamber systems which may provide access to multiple processing chambers while maintaining a vacuum environment in various sections, such as the noted holding and transfer areas, may allow operations to be performed in multiple chambers while maintaining a particular vacuum environment between discrete processes.

The processing system 100, or more specifically, chambers incorporated into the processing system 100 or other processing systems, may be used to produce structures according to some embodiments of the present disclosure. For example, the processing system 100 may be used to produce memory arrays by performing operations such as deposition, etch, sputtering, polishing, cleaning, and so forth, in the various substrate processing chambers 108a-f.

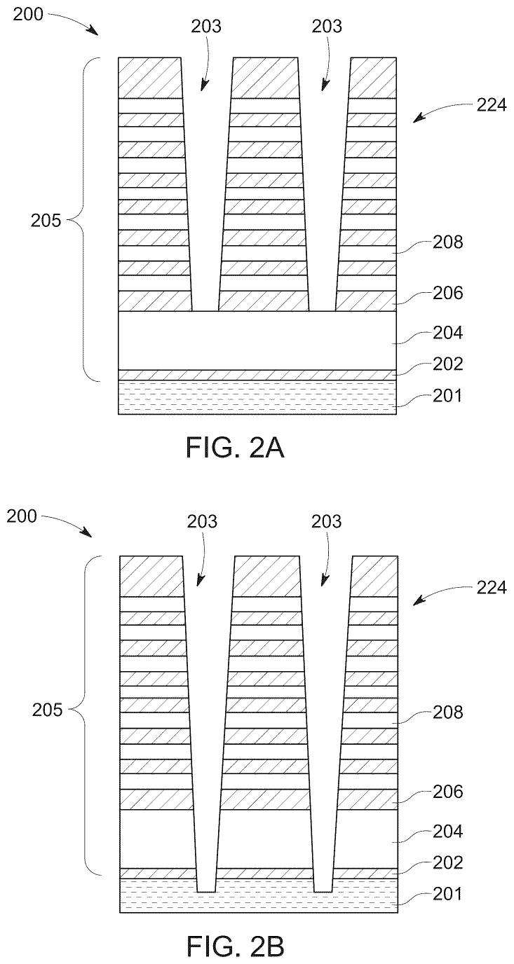

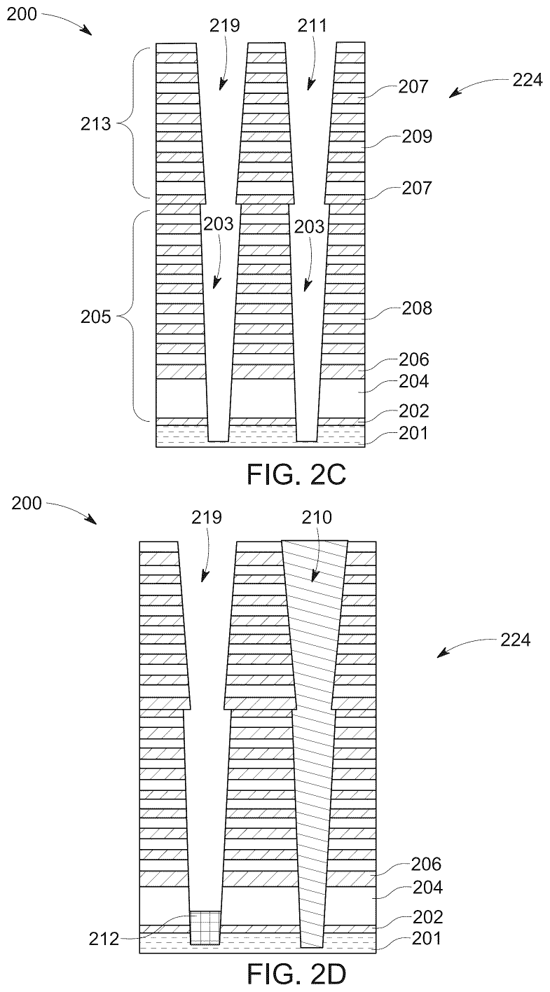

FIG. 2A illustrates a side cross-sectional view of a memory device (hereinafter “device”) 200 at an early stage of processing, according to one or more embodiments described herein. The device 200 may be a partial stack of alternating oxide-nitride layers formed for a 3D NAND flash array, for example. Each of the layers illustrated in FIG. 2A may be formed incrementally, one layer on top of the previous layer using any deposition or layer formation techniques. In this example, the layers may be formed on a substrate 201 of a silicon material, such as an epitaxial silicon or a single-crystal silicon wafer. A silicon oxide layer 202 may be formed over the substrate 201, followed by a silicon nitride layer 204. In some embodiments, the silicon oxide layer 202 and the silicon nitride layer 204 may represent initial layers on the substrate 201, and these layers may be thicker than the alternating oxide-nitride layers formed thereon. Next, alternating layers of silicon oxide 206 and silicon nitride 208 may be formed in a stack.

The progressive formation of the substrate 201, silicon oxide layers 206, silicon nitride layers 208, and other materials described below may be collectively referred to as a stack 224. As illustrated in FIG. 2A, the stack 224 may initially be of a limited height. For example, the finished stack 224 may have a very large number of layers (e.g., 128 pairs of alternating oxide and nitride layers). However, initially forming all of these layers may result in the stack 224 having an aspect ratio that is too high to reliably form the narrow channel holes and other vias that penetrate the entire stack 224. Therefore, the stack 224 may be formed in a series of tiers, wherein the alternating silicon oxide layers 206 and silicon nitride layers 208 correspond to a first tier 205.

As further shown in FIG. 2A, the stack 224 may be etched to form a plurality of channel holes 203 that penetrate the alternating silicon oxide layers 206 and silicon nitride layers 208. The channel holes 203 may be formed by layering a mask (not shown) over the partial stack and performing an etch process to remove material that is exposed by the mask. Any etch process may be used, and some embodiments may use a dielectric etch. Etching through the alternating silicon oxide layers 206 and silicon nitride layers 208 may benefit from a dielectric etch because the desired aspect ratio of the channel holes 203 for the device channels is relatively high (i.e., the vertical depth of the channel holes 203 is relatively large in comparison to the horizontal width of the channel holes 203). Generally, the depth of the channel holes 203 may be controlled based on the number of silicon oxide layers 206 and the number of silicon nitride layers 208 to be etched. For example, a time during which the etch process is allowed to run may be determined by the number of silicon oxide layers 206 and the number of silicon nitride layers 208 along the thicknesses of these layers. For example, some embodiments may etch the channel holes 203 down to the silicon nitride layer 204. Other embodiments may etch the channel holes 203 down to the silicon oxide layer 202, or down to the top of the substrate 201. The non-limiting example illustrated in FIG. 2A stops the etch at the top of the silicon nitride layer 204.

FIG. 2B illustrates how a bottom-punch etch may be used to penetrate the substrate 201 to expose the silicon of the substrate 201, according to some embodiments. In some embodiments, the dielectric etch used in FIG. 2B may stop the channel-hole etch before the etch penetrates the substrate 201. A second etch process may then be performed such that the channel holes 203 extend down into the substrate 201. This additional etch may be a directional etch oriented vertically towards the bottom of the channel holes 203 and may be referred to herein as a “bottom punch” etch. The bottom punch etch may allow the silicon material of the substrate 201 to be exposed at the bottom of the channel holes 203.

In some embodiments, the bottom punch etch may represent a separate etch from the etch used to form the channel holes 203. For example, the bottom punch etch may be performed in a conductor etch chamber instead of a dielectric etch chamber, which may have better critical dimension uniformity and profile tuning than the dielectric etch used to initially form the channel holes 203 for the device channels. The bottom punch may thus extend the channel holes 203 down into the substrate 201 to expose the silicon material. For example, the bottom punch etch may extend to the top surface of the substrate 201, or alternatively may penetrate into the substrate 201 below the top surface of the substrate 201. Alternatively, other embodiments may etch the entire length of the channel holes 203 down into the substrate 201 using a single etch process, thus combining the results of FIGS. 2A-2B into a single processing step. The exposed silicon material of the substrate 201 may be used in later steps to epitaxially grow silicon through the channels that form the 3D NAND flash memory cells.

FIG. 2C illustrates how the stack 224 may be extended by adding a second tier 213 atop the first tier 205, wherein the second tier 213 may include additional silicon oxide layers 207 and silicon nitride layers 209. These additional layers may be formed incrementally on top of the first tier 205. Although not shown, a support layer may first be formed within the channel holes 203 provide a base upon which the second tier 213 may be built. After adding the additional silicon oxide layers 207 and silicon nitride layers 209 of the second tier 213, a plurality of holes 211, 219 may be etched into the second tier 213, as illustrated. Note that these holes 211, 219 may be formed using a similar mask as was previously used to etch the channel holes 203 in the first tier 205. By incrementally etching these layer sets, a very high aspect ratio may be achieved, despite the depth of the holes 211, 219 in the full stack 224.

In practice, the stack 224 may include a large number of layers, a large number of channel holes, and may be used to form many hundreds of 3D NAND flash memory cells. However, these figures have been simplified to show the formation of a single epi silicon channel and the adjacent support structures or slits in the memory array. For example, an actual stack may include thousands of channels, more than 100 alternating oxide and nitride layers, and multiple slits and support structures. These layers may be formed in multiple processes, with etch operations performed incrementally on each batch of layers as they are added to the partial stack. Thus, although FIG. 2C illustrates only two partial stacks being combined, it should be understood that many additional partial stacks may be layered and etched to form the channel holes 203 through the stack 224. For example, some embodiments may include the combination of two partial stacks, each with approximately 128 alternating oxide-nitride layers for a total of 256 alternating oxide-nitride layers.

FIG. 2D illustrates an optional support feature 210 that may be formed in one of the holes, e.g., hole 211, to provide support to the stack 224 during the subsequent steps of the process, according to some embodiments. The support feature 210 may be selectively deposited in one of the holes in order to form a rigid structure through the first tier 205 and the second tier 213. For example, some embodiments may use a metal, such as tungsten to form the support feature 210. Some embodiments may use a dielectric fill such as a SiOx or a MANOS stack for the support feature 210. Any deposition process may be used to form the support feature 210. Note that the support feature 210 may extend down into the substrate 201 by virtue of the etch process described above that overshoots the last silicon oxide layer 202. The support feature 210 keeps the layers of the stack 224 from collapsing when the silicon nitride layer 204 is removed. Furthermore, extending the support feature 210 down into the substrate 201 prevents any movement of the upper layers of the stack 224 when the silicon nitride layer 204 is later removed.

FIG. 2D further illustrates an initial layer of epitaxial silicon 212 formed in one of the holes 219, according to some embodiments. As mentioned above, the additional depth of the bottom punch etch into the substrate 201 exposes the silicon material of the substrate 201 to the hole 219. Because the single-crystal silicon of the substrate 201 is exposed, the layer of epitaxial silicon 212 may be grown in the channel hole using processes such as silicon epitaxial deposition or epitaxy that grows thin layers of single-crystal silicon over the single-crystal silicon substrate 201. For example, some embodiments may perform the epitaxy process through chemical vapor deposition. Materials such as silicon tetrachloride, trichlorosilane, Di chlorosilane, silane, and other chemical sources of silicon may be provided to the deposition chamber to incrementally form the epitaxial silicon 212 that is grown on top of the substrate 201. The height of the epitaxial silicon 212 may be above the silicon oxide layer 202, but below the next silicon oxide layer 206 in the stack 224. For example, the height of the epitaxial silicon 212 may be within the sacrificial nitride layer 204.

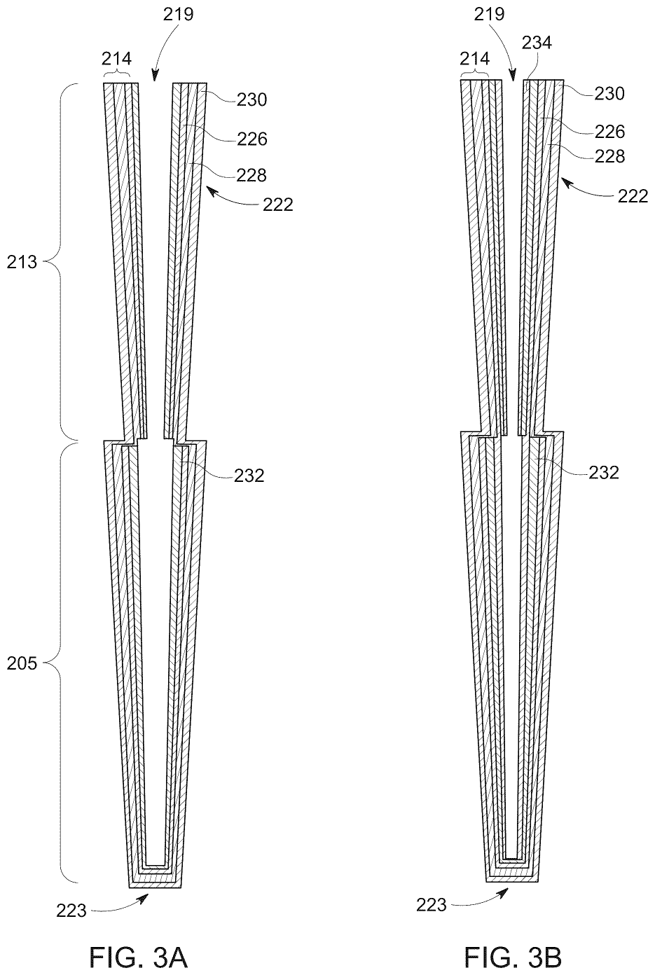

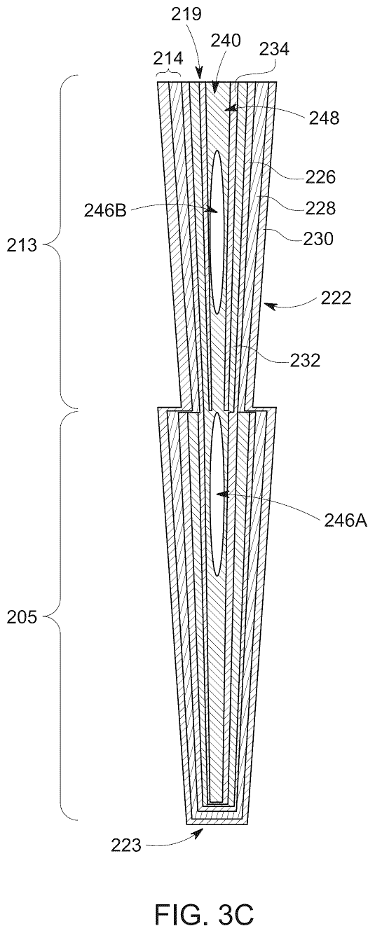

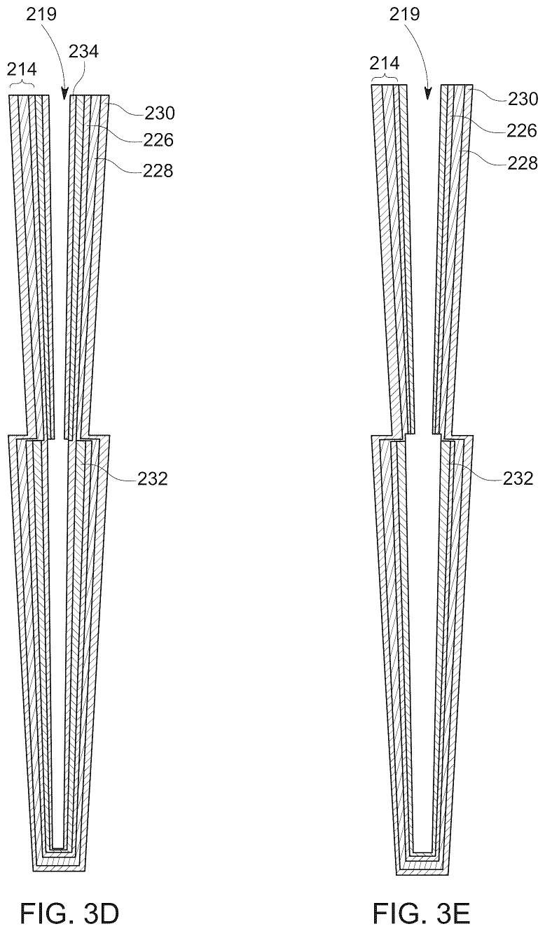

FIG. 3A illustrates the hole 219 of FIG. 2D in greater detail. The rest of the device 200 is not shown for the sake of clarity. Since the hole 219 may now be used to form a channel for a vertical column of 3D NAND memory cells, the hole 219 may also be referred to herein as a channel hole. As shown, a tunneling layer 214 may be formed along one or more sidewalls 222 and along a bottom 223 of the channeling hole 219, wherein the tunneling layer 214 and the channeling hole 219 extend through the first tier 205 and the second tier 213 of the stack 224. The tunneling layer 214 may be formed by depositing a first blocking dielectric or oxide 226, a charge trap nitride (e.g., silicon nitride) 228, and a second tunneling dielectric or oxide 230. These three layers may be collectively referred to as the ONO layer or as the tunneling layer 214 in this disclosure. The first and second oxide layers 226, 230 in the tunneling layer 214 may provide an offset for the conduction band and the valence band for the transistor devices of the memory cells. Although non-limiting, the channeling hole 219 may be approximately 20 μm deep in some embodiments. As shown, the sidewalls 222 of the channeling hole 219 may be nonparallel. More specifically, the sidewalls 222 the channeling hole 219 generally converge towards the bottom 223 of the channeling hole 219.

The various layers of the tunneling layer 214 may be formed using atomic layer deposition, and thus the layers of the tunneling layer 214 may be relatively thin compared to the alternating oxide-nitride layers of the stack 224. This process may cause the tunneling layer 214 to grow on the sidewall(s) 222 and the bottom 223 of the channel hole 219, over the top of the epitaxial silicon 212 (FIG. 2D). Because the epitaxial silicon 212 stops before the alternating silicon oxide layers 206 and silicon nitride layers 208, the interior of the channel for the 3D NAND memory cells may be covered with the tunneling layer 214.

FIG. 3A further illustrates deposition of a channel liner 232, over the tunneling layer 214 within the channel hole 219. The channel liner 232 may be a layer of silicon formed using atomic layer deposition, and thus may be relatively thin compared to the alternating oxide-nitride layers of the stack 224. This process may cause the channel liner 232 to grow on the tunneling layer 214.

FIG. 3B demonstrates an etch stop layer 234 formed over/along the channel liner 232. In some embodiments, the etch stop layer 234 may be a layer of SiO formed using atomic layer deposition, and thus may be relatively thin (e.g., approximately 5 nm).

FIG. 3C demonstrates formation of a fluorine-doped layer 240 over the etch stop layer 234 and the tunneling layer 214 within the channel hole 219. The fluorine-doped layer 240 may be a film layer formed using chemical vapor deposition (CVD), and may be formed over the sidewall(s) 222 and the bottom 223 of the channel hole 219. More specifically, a silicon film may be deposited within the channel hole 219 and then implanted with fluorine. That is, fluorine atoms may be directed into an outer surface of the silicon film. In other embodiments, the silicon film may be deposited with fluorine already incorporated therein. In some non-limiting embodiments, the fluorine-doped silicon film comprises approximately 3-6% fluorine. At this ratio, the ON current may be increased approximately 5× and the variability reduced by approximately 6σ. Furthermore, the fluorine concentration at channel/Tox may be approximately 4c20 cm-3, and the concertation of fluorine inside the Tox may be below 4c20 cm-3.

As further demonstrated in FIG. 3C, one or more voids or gaps may result in the channel hole 219 following formation of the fluorine-doped layer 240. In some embodiments a first void 246A can be formed in the first tier 205, and a second void 246B can be formed in the second tier 213. As shown, a first portion 248 of the fluorine-doped layer 240 extends between each side wall of the etch stop layer 234 to enclose the second void 246B. Although nonlimiting, the first void 246A can be formed towards a top portion of the first tier 205, while the second void 246B can be formed towards a middle portion of the second tier 213.

Following formation of the fluorine-doped layer 240, an annealing process may then be performed. In some embodiments, the annealing process may be performed at a temperature greater than 500° C. In one non-limiting example, the annealing process may be performed at 650° C. for between 45 and 80 seconds. The annealing process helps diffuse the fluorine into the channel.

FIG. 3D illustrates the selective removal of the fluorine-doped layer 240 (FIG. 3C) of the stack 224 following the annealing process. In this example, a wet etch may be used, such as a tetramethylammonium hydroxide (TMAH) chemical etch. The wet etch may remove the fluorine-doped layer 240 selective to the etch stop layer 234. Other embodiments may use dry etches or other processes that are configured to selectively fluorine-doped layer 240.

FIG. 3E illustrates the selective removal of the etch stop layer 234, according to some embodiments. In this example, a wet or dry etch may be used to remove the etch stop layer 234 selective to the channel liner 232.

Although not shown, the channel hole 219 may then be filled with a core gap fill material, according to some embodiments. In order to protect the tunneling layer 214 and the channel liner 232 during subsequent etch processes, the channel hole 219 may be filled with the core gap fill material, which may be SiO. The core gap fill material 216 may be formed directly atop the channel liner 232.

Although not shown, further processes may be later performed on the device 200 to complete the memory array. These operations are beyond the scope of this disclosure, and are therefore omitted for the sake of brevity.

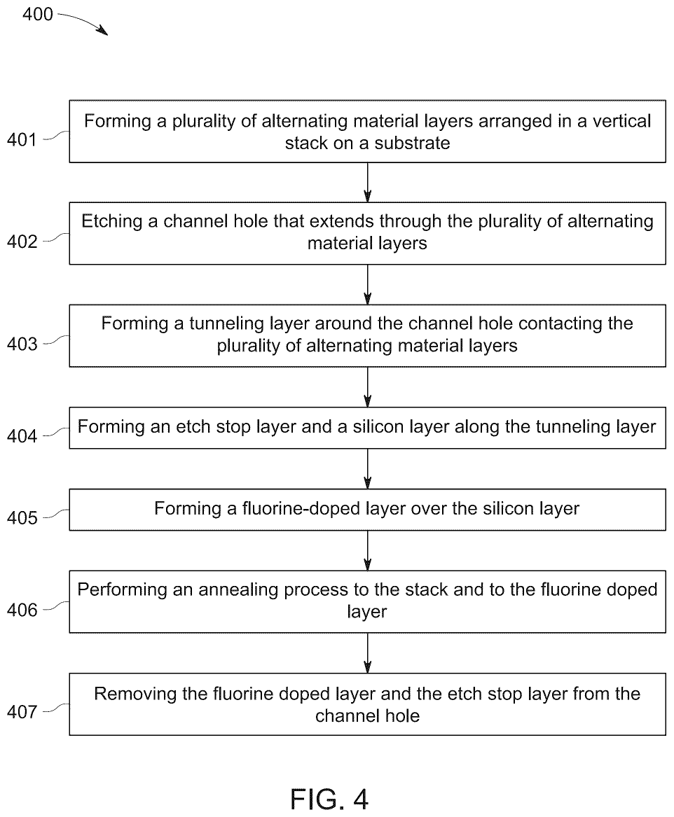

FIG. 4 illustrates a flowchart 400 of a method for fabricating a 3D NAND memory structure, according to some embodiments. This method may be executed in various processing chambers in a semiconductor processing system, e.g., as illustrated in FIG. 1.

At block 401, the method may include forming a plurality of alternating material layers arranged in a vertical stack on a substrate. In some embodiments, the alternating material layers include alternating layers of an oxide material and a nitride material. In some embodiments, the alternating material layers include alternating layers of the oxide material and a metal, wherein the metal forms a gate electrode for individual memory cells.

At block 402, the method may include etching, or otherwise forming, a channel hole that extends through the plurality of alternating material layers. In some embodiments, the channeling hole extends to the top surface of the substrate.

At block 403, the method may include forming an oxide/nitride/oxide+polysilicon (ONOP) tunneling layer around the channel hole, wherein the ONOP layer contacts the plurality of alternating material layers.

At block 404, the method may include forming an etch stop layer and along the ONOP layer. In some embodiments, the etch stop layer may be deposited via ALD. In some embodiments, the etch stop layer may be SiO.

At block 405, the method may include forming a fluorine-doped layer over the etch stop layer. In some embodiments the fluorine-doped layer is a fluorine-doped film formed via CVD. In some embodiments, one or more gaps or voids may be formed in the fluorine-doped layer.

At block 406, method may include performing an annealing process to the stack and to the fluorine-doped layer.

At block 407, the method may include removing the fluorine-doped layer and the etch stop layer from the channel hole. In various embodiments, one or more wet or dry etch processes may be performed to remove the fluorine doped layer and the etch stop layer.

It should be appreciated that the specific steps illustrated in FIG. 4 provide particular methods of fabricating a 3D NAND memory structure according to various embodiments. Other sequences of steps may also be performed according to alternative embodiments. For example, alternative embodiments may perform the steps outlined above in a different order. Moreover, the individual steps illustrated in FIG. 4 may include multiple sub-steps that may be performed in various sequences as appropriate to the individual step. Furthermore, additional steps may be added or removed depending on the particular application. Many variations, modifications, and alternatives also fall within the scope of this disclosure.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method comprising:
forming a channel hole through a vertical stack, the vertical stack comprising a plurality of alternating material layers;
forming a tunneling layer along a sidewall of the channel hole;
forming a channel liner over the tunneling layer;
forming an etch stop layer over the channel liner;
forming a doped film layer over the etch stop layer; and
annealing the vertical stack.

2. The method of claim 1, further comprising removing the doped film layer selective to the etch stop layer after the vertical stack is annealed.

3. The method of claim 2, further comprising removing the etch stop layer after the doped film layer is removed.

4. The method of claim 2, wherein the doped film layer is removed using a wet etch.

5. The method of claim 1, wherein forming the doped film layer comprises:
depositing a silicon film directly atop the etch stop layer; and
directing fluorine ions into the silicon film to form a fluorine-doped silicon film.

6. The method of claim 5, further comprising forming a void in the fluorine-doped silicon film.

7. The method of claim 6, further comprising forming the vertical stack over a substrate by:
forming a first tier of layers of the plurality of alternating material layers; and
forming a second tier of layers of the plurality of alternating layers over the first tier of layers of the plurality of alternating material layers.

8. The method of claim 7, wherein the void in the fluorine-doped silicon film is formed in the first tier of layers of the plurality of alternating material layers, and wherein a second void in the fluorine-doped silicon film is formed in the second tier of layers of the plurality of alternating layers.

9. The method of claim 1, wherein the plurality of alternating material layers comprises alternating layers of oxide and nitride.

10. A method of forming a three-dimensional (3D) NAND memory structure, the method comprising:
forming a vertical stack over a substrate, the vertical stack comprising a plurality of alternating material layers;
forming a channel hole through the vertical stack;
forming a tunneling layer along a sidewall and along a bottom of the channel hole, wherein the tunneling layer comprises a first oxide, a nitride, and a second oxide;
forming a silicon layer over the tunneling layer;
forming an etch stop layer over the silicon layer;
forming a fluorine-doped silicon layer over the etch stop layer; and
annealing the vertical stack.

11. The method of claim 10, further comprising:
removing the fluorine-doped silicon layer selective to the etch stop layer after the vertical stack is annealed, wherein the etch stop layer is removed using a wet etch; and
removing the etch stop layer after the fluorine-doped silicon layer is removed.

12. The method of claim 10, wherein forming the fluorine-doped silicon layer comprises:
depositing a silicon film directly atop the etch stop layer; and
directing fluorine ions into the silicon film to form a fluorine-doped film.

13. The method of claim 12, wherein forming the vertical stack over the substrate comprises:
forming a first tier of layers of the plurality of alternating material layers; and
forming a second tier of layers of the plurality of alternating layers over the first tier of layers of the plurality of alternating material layers, wherein a void in the fluorine-doped film is formed in the first tier of layers of the plurality of alternating material layers, and wherein a second void in the fluorine-doped film is formed in the second tier of layers of the plurality of alternating layers.

14. The method of claim 10, wherein the plurality of alternating material layers comprises alternating layers of oxide and nitride.

15. A method of forming a memory device, the method comprising:
forming a vertical stack over a substrate, the vertical stack comprising a plurality of alternating material layers;
forming a channel hole through the vertical stack;
forming an oxide-nitride-oxide layer along a sidewall and along a bottom of the channel hole;
forming a silicon layer over the oxide-nitride-oxide layer;
forming an etch stop layer over the silicon layer;
forming a fluorine-doped silicon film over the etch stop layer; and
annealing the vertical stack including the fluorine-doped silicon film.

16. The method of claim 15, further comprising:
removing the fluorine-doped silicon film selective to the etch stop layer after the vertical stack is annealed; and
removing the etch stop layer after the fluorine-doped silicon film is removed.

17. The method of claim 16, wherein the fluorine doped layer is removed using a wet etch.

18. The method of claim 15, wherein forming the vertical stack over the substrate comprises:
forming a first tier of layers of the plurality of alternating material layers; and
forming a second tier of layers of the plurality of alternating layers over the first tier of layers of the plurality of alternating material layers, wherein a void in the fluorine-doped film is formed in the first tier of layers of the plurality of alternating material layers, and wherein a second void in the fluorine-doped film is formed in the second tier of layers of the plurality of alternating layers.

19. The method of claim 15, wherein the plurality of alternating material layers comprises alternating layers of oxide and nitride.

20. The method of claim 15, wherein the annealing is performed at a temperature greater than 500 degrees Celsius, and wherein a concentration of fluorine in the fluorine-doped silicon film is between 3-6%.
